(19) United States
(12) Patent Application Publication
(10) Pub. No.: US 2005/0068210 A1
(43) Pub. Date: Mar. 31, 2005

(54) Apparatus and method for measuring data converter

(76) Inventor: Chun Wei Lin, Changhua (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/770,548

(22) Filed: Feb. 4, 2004

(30) Foreign Application Priority Data
Sep. 17, 2003 (TW) 092125550

(51) Int. Cl. H03M 1/10; H03M 1/00

(52) U.S. Cl. 341/120; 341/141

(57) ABSTRACT

The present apparatus for measuring data converter comprises a digital-to-analog converter, a multiplexer, a histogram analyzer and a software engine. The digital-to-analog converter is intended to generate uniform pseudo-random signals. The multiplexer selects an output of the digital-to-analog converter or an external analog input signal and sends it to a data converter under test. The histogram analyzer is electrically connected to the output of the data converter under test, so as to display the frequency of the appearance of various codes of the converter. The software engine is electrically connected to the output of the histogram analyzer, so as to display the characteristics of the data converter under test.

### BACKGROUND OF THE INVENTION

1. Field of the Invention

The present invention relates to a measurement apparatus for data converter and the method thereof, and more particularly, to a measurement apparatus for data converter and the method thereof using uniform pseudo-random patterns as measurement input signals.

2. Background of the Invention

Widely applied to various electronic products, data converters (for example, analog-to-digital converters), whether in the form of embedded chips or stand-alone chips, determine the ultimate accuracy of an electronic product to a great extent according to their design and the reliability and accuracy of their manufacturing process. Therefore, an accurate measurement and even a suitable adjustment in the output characteristics of a data converter are of vital importance.

A conventional measurement apparatus for a data converter uses Gauss distribution pattern as the measurement input, in order to measure the static characteristics of the data converter. Furthermore, with an independent measurement path, it measures the dynamic characteristics of the data converter by inputting a sine wave signal. However, the conventional method results in a lengthy measurement process and a complicated design.

US 2002/0158783 A1 discloses a method for measuring the linearity of analog-to-digital converters. The method allows noise to be removed by a digital filter installed in front of the histogram generator. US 2003/0030615 A1 discloses a model building phase and the formulation of a measurement strategy to shorten measurement duration. Nevertheless, the conventional techniques still involve using uniform pseudo-random patterns as measurement input signals and thus they are not free of the aforesaid shortcomings.

### SUMMARY OF THE INVENTION

The primary purpose of the present invention is to provide a measurement apparatus for data converter and the method thereof using uniform pseudo-random patterns as input signals for measurement in order to make the design less complicated.

The second purpose of the present invention is to provide a measurement apparatus for data converter and the method thereof using the same histograms in analyzing both static parameters and dynamic parameters.

The third purpose of the present invention is to provide a measurement apparatus for data converter and the method thereof using the bisection method to achieve normalization and compensate for the errors of a digital-to-analog converter.

In order to achieve the aforesaid purposes, the present invention discloses a measurement apparatus for data converter and the method thereof, where the measurement apparatus comprises a digital-to-analog converter, a multiplexer, a histogram analyzer and a software engine. The digital-to-analog converter is intended to generate uniform pseudo-random signals. The multiplexer selects an output of the digital-to-analog converter or an external analog input signal and sends it to a data converter under test. The histogram analyzer is electrically connected to the output of the data converter under test, so as to display the frequency of the appearance of various codes of the converter. The software engine is electrically connected to the output of the histogram analyzer, so as to display the characteristics of the data converter under test.

As for the data converter according to the present invention, it is operated with a measurement method, which involves step (a) through step (e). In step (a), uniform pseudo-random signals are generated and sent to a data converter under test. In step (b), histograms to be output by the data converter under test are created. In step (c), errors, which are not derived from the data converter under test, are compensated for. Step (d) involves calculating the static parameters of the data converter under test. Step (e) involves calculating the dynamic parameters of the data converter under test.

According to the present invention, the measurement apparatus for the data converter enables a design engineer to gain an insight into whatever errors are embodied in the design of a data converter under test at as early as the design stage. Moreover, during the production stage, it helps the design engineer understand manufacturing process errors related to the data converter under test.

### BRIEF DESCRIPTION OF THE DRAWINGS

The present invention will be described according to the appended drawings in which:

FIG. 1 is a schematic view of the apparatus for measuring data converter according to the present invention;

FIG. 2 is a schematic view of the digital-to-analog converter according to the present invention;

FIGS. 3(a) and 3(b) show waveforms of a prior art and the present histogram analyzers;

FIG. 4 is a schematic view of the structure of the software engine according to the present invention;

FIG. 5 shows a schematic view of the bisection method and the piecewise-linear model used in the compensator according to the present invention;

FIG. 6 is a schematic view of an adaptive architecture; and

FIGS. 7(a) to 7(c) depict a flowchart of converting a histogram into a time domain waveform in accordance with the present invention.

### DESCRIPTION OF THE PREFERRED EMBODIMENTS

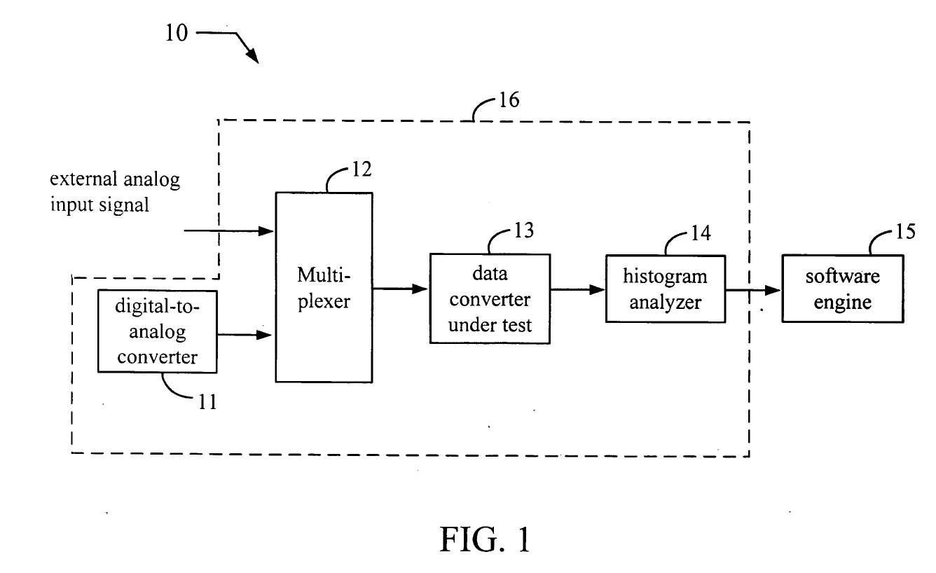

FIG. 1 is a schematic view of the apparatus for measuring data converter according to the present invention. The apparatus for measuring data converter 10 comprises a digital-to-analog converter 11, a multiplexer 12, a histogram analyzer 14 and a software engine 15. The apparatus for measuring data converter 10 is designed to measure errors of a data converter under test 13 (e.g., an analog-to-digital converter). The data converter under test 13 can be either an embedded circuit or a stand-alone chip. The multiplexer 12 selects an output of the digital-to-analog converter 11 or an external analog input signal, and then sends it to the data converter under test 13.

As for the composition of the apparatus for measuring data converter 10 according to the present invention, it can be roughly divided into two regions, namely a hardware region and a software region. The hardware region contains the digital-to-analog converter 11, the multiplexer 12 and the histogram analyzer 14, all of which may be embodied in a chip 16 along with the data converter under test 13. The software region contains the software engine 15. However, in practice, both the hardware region and the software region may be further modified, if necessary.

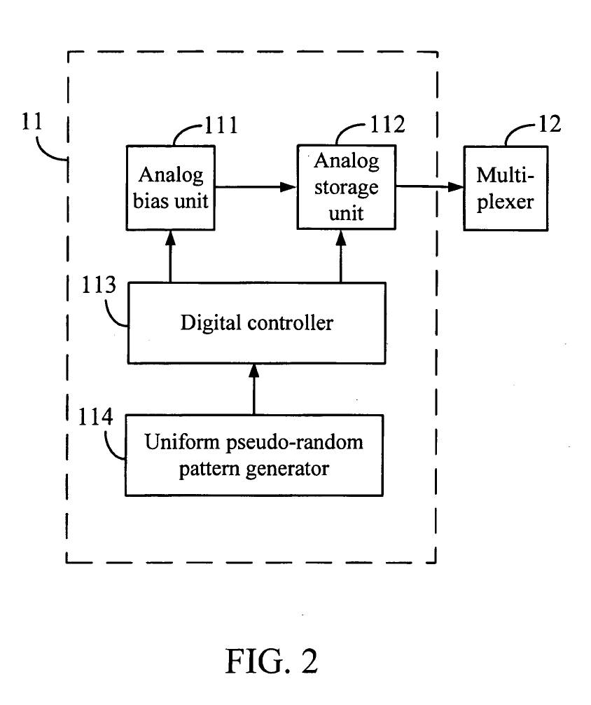

FIG. 2 is a schematic view of the digital-to-analog converter 11. The digital-to-analog converter 11 comprises an analog bias unit 111, an analog storage unit 112, a digital controller 113 and a uniform pseudo-random pattern generator 114. The digital controller 113 converts the output format of the uniform pseudo-random pattern generator 114, e.g., performing a serial to parallel conversion or normalization. The analog bias unit 111 provides a bias signal for the analog storage unit 112, which converts uniform pseudo-random signals output from the digital controller 113 into analog signals and then sends to the data converter under test 13 through the multiplexer 12. In the measurement stage, the digital-to-analog converter 11 generates uniform pseudo-random signals, and the multiplexer 12 retrieves the output of the digital-to-analog converter 11. On receiving the uniform pseudo-random signals, the data converter under test 13 sends the corresponding output to the histogram analyzer 14. As shown in equation 1, the output Z=X+Y is a uniform pseudo-random pattern regardless of the interference from any nonlinear noise Y (assuming it is a Gauss distribution), provided that the variance 6 is insignificant and the mean μ is equal to 0. The underlying reason for this is that, the input X of the data converter under test 13 is a uniform pseudo-random pattern.
X˜U(α,β): uniform pseudo-random signal

$${f}_{X} ( x ) = \frac{1}{β - α} , α \leq x \leq β$$
Y˜N(μ,σ²) nonlinear noise

$${f}_{Y} ( y ) = \frac{1}{σ \sqrt{2 π}} {ⅇ}^{\frac{- 1}{2} {( \frac{y - μ}{σ} )}^{2}} , - ∞ \leq y \leq ∞$$

$${f}_{Z} ( z ) = \frac{1}{β - α} Φ ( \frac{y - μ}{σ} ) \vert \begin{matrix}y = z - α \\ y = z - β\end{matrix}$$
If σ is insignificant and μ=0

$$⇒ Φ ( \frac{z - α}{σ} ) - Φ ( \frac{z - β}{σ} ) = 1 \\ ⇒ {f}_{Z} ( z ) \approx \frac{1}{β - α} ∼ U ( α , β ) \qquad ( equation 1 )$$

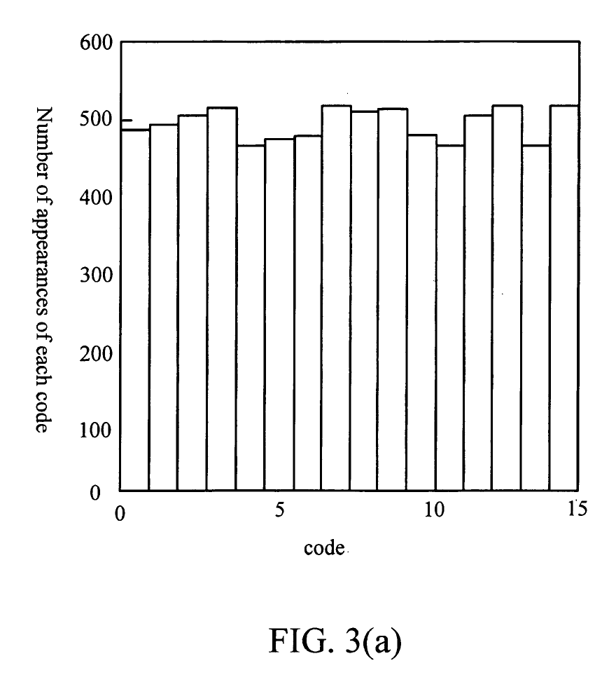

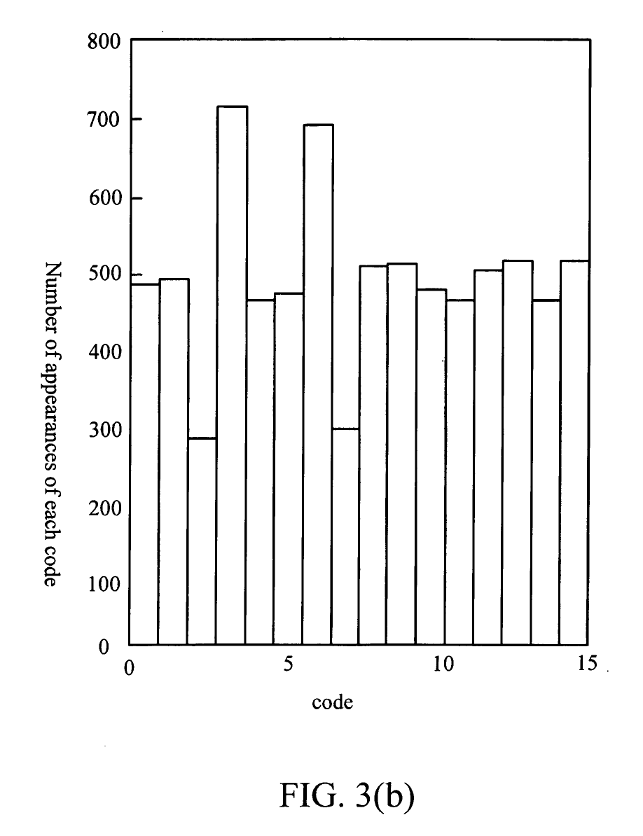

As shown in FIG. 3(a), an error-free data converter under test 13 will display a quite uniform waveform on the histogram analyzer 14. As shown in FIG. 3(b), a waveform displaying on the histogram analyzer 14 and showing amplitude with great vibration indicates that the data converter under test 13 has a considerable error.

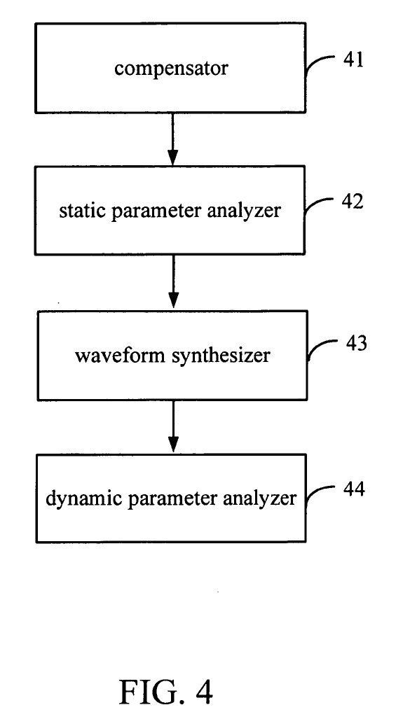

FIG. 4 is a schematic view of the structure of the software engine according to the present invention. The software engine comprises a compensator 41, a static parameter analyzer 42, a waveform synthesizer 43 and a dynamic parameter analyzer 44. Designed to compensate for the errors of the digital-to-analog converter 11, the compensator 41 filters out and displays the error of the data converter under test 13 by means of its inside adaptive architecture. The static parameter analyzer 42 calculates conventional parameters like DNL and INL in the light of the output of the compensator 41. The waveform synthesizer 43 converts a histogram output by the compensator 41 into a trigonometric histogram of a probability domain and then transfers it into a time domain waveform through a constant sampling method, so as to overcome the problem that a conventional technique requires inputting a sine wave additionally for the sake of dynamic analysis. The time domain waveform generated by the waveform synthesizer 43 becomes the input of the dynamic parameter analyzer 44, thus it is not necessary to apply an additional sine wave in order to calculate a conventional parameter, such as signal to noise ratio (SNR).

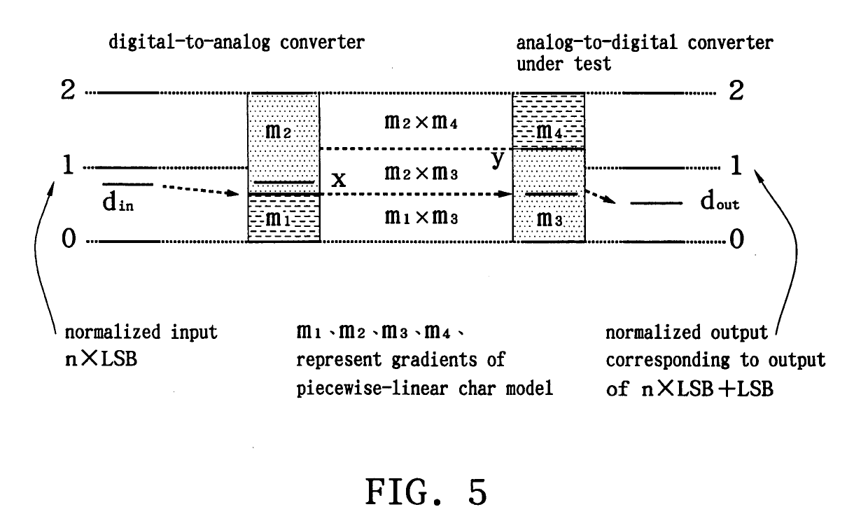

Either the piecewise-linear model or the bisection method may be applied to the compensator 41 of the present invention. The latter allows a uniform pseudo-random pattern to have an effect identical to that of a Gauss distribution. As mentioned above, the purpose of the compensator 41 is to compensate for errors of the digital-to-analog converter 11, so that the apparatus for measuring data converter 10 can single out and display the error of the data converter under test 13. As shown in FIG. 5, the assumptions are as follows. Neither the digital-to-analog converter 11 nor the data converter under test 13 is free from errors. The symbol x denotes the quantization level of the digital-to-analog converter 11. The symbol y denotes the quantization level of the data converter under test 13. Both x and y are the real analog transition levels. Before working with the bisection method, it is necessary to perform normalization, that is, treating any input signal or output signal less than the quantization level as 0 and treating any input signal or output signal greater than the quantization level as 1. As regards the order of the operating steps, it is necessary for the compensator 41 to figure out the respective quantization levels of the codes of the digital-to-analog converter 11. Assuming that the digital-to-analog converter 11 has a normalized input of n×LSB, wherein n denotes the code and LSB denotes the fundamental unit of the quantization level, it is necessary to calculate the sum of the corresponding output of the data converter under test 13 and one LSB together, which acts as the quantization level of the data converter under test 13 when normalization is performed. As regards the calculation done with the bisection method, the piecewise-linear model of the digital-to-analog converter 11 has gradients m₁ and m₂, respectively, whereas the piecewise-linear model of the data converter under test 13 has gradients m₃ and m₄, respectively, thus there are a total of three different gradients between the input (dᵢₙ) and the output (dₒᵤₜ), namely m₁×m₃, m₂×m₃ and m₂×m₄, which satisfy the underlying equation 2.

$$\frac{x}{y} = {m}_{1} \times {m}_{3} \\ \frac{2 - x}{y} = {m}_{2} \times {m}_{3} ⇒ x = \frac{2}{1 + \frac{{m}_{2} \times {m}_{3}}{{m}_{1} \times {m}_{3}}} \\ \frac{2 - x}{2 - y} = {m}_{2} \times {m}_{4} \qquad ( equation 2 )$$

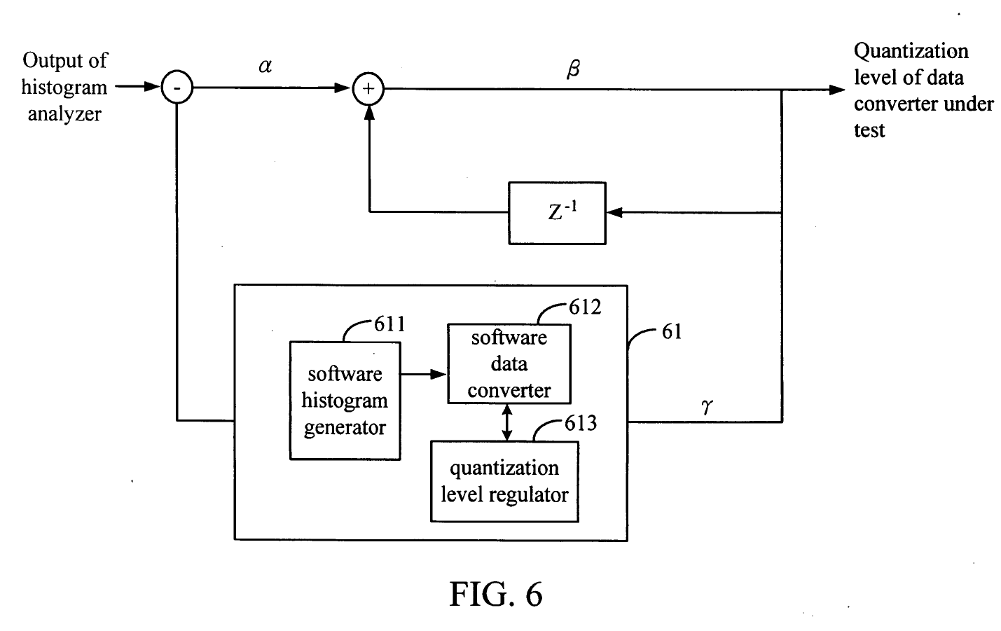

The step 2 for the compensator 41 involves eliminating the error-related factors of the digital-to-analog converter 11 by means of an adaptive architecture (e.g., a conventional delta-sigma architecture) and working out the quantization level and the histogram solely relevant to the data converter under test 13. FIG. 6 is a schematic view of an adaptive architecture, where it gradually eliminates the error-related factors of the digital-to-analog converter 11 by means of heuristic, repetitious circulation. As shown in FIG. 6, a regulator 61 comprises a software histogram generator 611, a software data converter 612 and a quantization level regulator 613. Knowing the error of the digital-to-analog converter 11, the regulator 61 makes adjustments in the output of the histogram analyzer 14 unceasingly, so that the adaptive architecture eventually acquires the quantization level of the data converter under test 13.

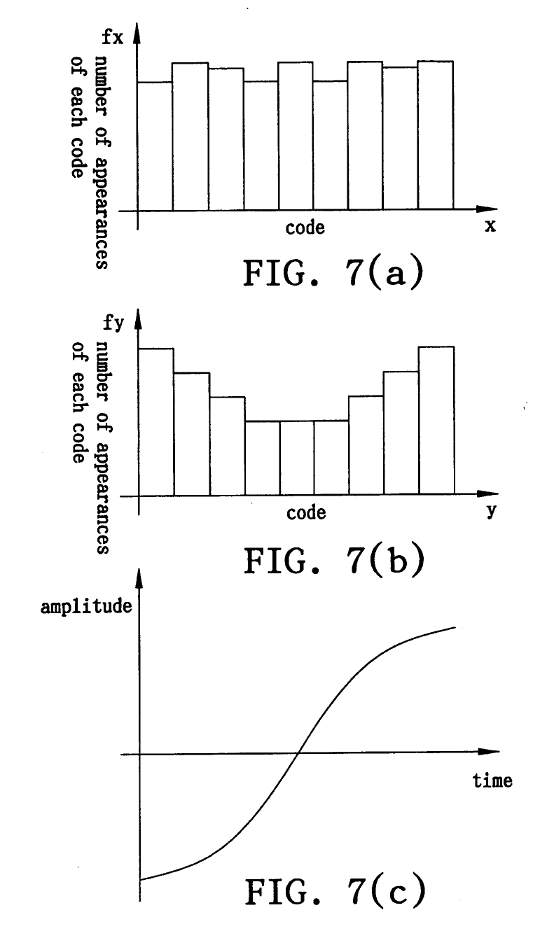

Another feature of the present invention is that a histogram may function as input patterns of the static parameter analyzer 42 and the dynamic parameter analyzer 44 in order to solve the problem that a conventional technique requires inputting a sine wave additionally for the sake of dynamic analysis. FIG. 7(a) is the output histogram of the compensator 41, where it, coupled with the convolution operation of a statistical equation P(n) (see equation 3), yields a trigonometric histogram of a probability domain, as illustrated in FIG. 7(b).
Fy=P(n)*fx where * denotes a convolution operation

$$P ( n ) = \frac{1}{π} [ {sin}^{- 1} ( \frac{B ( n - {2}^{N - 1} )}{A \times {2}^{N}} ) - {sin}^{- 1} ( \frac{B ( n - 1 - {2}^{N - 1} )}{A \times {2}^{N}} ) ] \qquad ( equation 3 )$$

In the above equation, n denotes the code, B denotes the full-scale range of the data converter under test 13, A denotes the amplitude of the sine wave, and N denotes the number of bits of the data converter under test 13.

As depicted in FIG. 7(c), with constant sampling, the waveform synthesizer 43 converts a histogram created by the data converter under test 13 in a probability domain into a time domain waveform. (This occurs as a result of rotating the bar chart of every code indicated by the vertical axis in FIG. 7(b) by 90 degrees and performing convolution on it in the direction of the horizontal axis in FIG. 7(c) step by step). The time domain waveform generated by the waveform synthesizer 43 becomes the input to the dynamic parameter analyzer 44, thus it is not necessary to apply an additional sine wave in order to calculate a conventional parameter, such as signal to noise ratio (SNR), with the dynamic parameter analyzer 44.

The above-described embodiments of the present invention are intended to be illustrative only. Numerous alternative embodiments may be devised by those skilled in the art without departing from the scope of the following claims.

1. An apparatus for measuring data converters, comprising:
a digital-to-analog converter for generating uniform pseudo-random signals;
a multiplexer for selecting the uniform pseudo-random signals or an external analog input signal to a data converter under test;
a histogram analyzer electrically connected to the output of the data converter under test; and
a software engine electrically connected to the output of the histogram analyzer so as to display characteristics of the data converter under test.

2. The apparatus for measuring data converters of claim 1, wherein the digital-to-analog converter comprises:
a uniform pseudo-random pattern generator;
a digital controller for converting the output format of the uniform pseudo-random pattern generator;
an analog storage unit electrically connected to the output of the digital controller and the multiplexer; and
an analog bias unit for providing a bias signal of the analog storage unit.

3. The apparatus for measuring data converters of claim 1, wherein the multiplexer selects the uniform pseudo-random signals when in a measurement stage, and selects the external analog input signal after the measurement stage.

4. The apparatus for measuring data converters of claim 1, wherein the software engine comprises:
a compensator for removing errors generated by the digital-to-analog converter;
a static parameter analyzer; and
a dynamic parameter analyzer.

5. The apparatus for measuring data converters of claim 4, wherein the software engine further comprises a waveform synthesizer, which first converts an output histogram of the histogram analyzer into a trigonometric histogram of a probability domain and then converts the trigonometric histogram into a time domain waveform by constant sampling.

6. The apparatus for measuring data converters of claim 5, wherein the time domain waveform generated by the waveform synthesizer acts as the input of the dynamic parameter analyzer.

7. The apparatus for measuring data converters of claim 4, wherein the compensator performs a piecewise-linear model or a bisection method.

8. The apparatus for measuring data converters of claim 4, wherein the compensator includes an adaptive architecture for filtering out errors of the data converter under test.

9. The apparatus for measuring data converters of claim 8, wherein the adaptive architecture comprises a regulator, which includes a software histogram generator, a software data converter and a quantization level regulator.

10. A method for measuring data converters, comprising the steps of:
generating and forwarding uniform pseudo-random signals to a data converter under test;
compensating for errors not derived from the data converter under test;
calculating static parameters of the data converter under test; and
calculating dynamic parameters of the data converter under test.

11. The method for measuring data converters of claim 10, wherein the static and dynamic parameters access a same histogram.

12. The method for measuring data converters of claim 10, further comprising the steps of:
converting the histogram used by the static parameters into a trigonometric histogram of a probability domain; and
converting the trigonometric histogram into a time domain waveform by constant sampling.

13. The method for measuring data converters of claim 10, wherein compensation for errors derived from the data converter under test is performed by an adaptive architecture.

14. The method for measuring data converters of claim 10, wherein compensation for errors not derived from the data converter under test is performed by a piecewise-linear model or a bisection method.

15. The method for measuring data converters of claim 10, wherein a device for generating the uniform pseudo-random signals and the data converter under test are manufactured in a single chip.

16. The method for measuring data converters of claim 10, wherein the steps of compensating errors not deriving from the data converter under test, calculating the static parameters of the data converter under test and calculating the dynamic parameters of the data converter under test are performed by a software engine.
